(19) United States
(12) Patent Application Publication
(10) Pub. No.: US 2025/0191654 A1
(43) Pub. Date: Jun. 12, 2025

(54) MEMORY ARRAY AND IN-MEMORY COMPUTING CIRCUIT

(71) Applicant: PEKING UNIVERSITY, Beijing (CN)

(72) Inventors: Zongwei WANG, Beijing (CN); Yimao CAI, Beijing (CN); Cuimei WANG, Beijing (CN); Jingwei SUN, Beijing (CN)

(21) Appl. No.: 18/966,686

(22) Filed: Dec. 3, 2024

(30) Foreign Application Priority Data
Dec. 6, 2023 (CN) 202311662692.1

(51) Int. Cl. G11C 13/00; G11C 11/16; G11C 11/22; H10B 80/00; H10D 64/23

(52) U.S. Cl. CPC G11C 13/004; G11C 11/1659; G11C 11/1673; G11C 11/2259; G11C 11/2273; G11C 13/003; H10B 80/00; H10D 64/251

(57) ABSTRACT

The present disclosure provides a memory array and an in-memory computing circuit, wherein the memory array comprises memory cells arranged in an array, and each of the memory cells comprises a first memory structure and a second memory structure complementary to each other, wherein, the first memory structure comprises a first transistor and a first memory connected to a drain electrode of the first transistor, the second memory structure comprises a second transistor and a second memory connected to a drain electrode of the second transistor, the first memory structure and the second memory structure are isolated from each other, and the first memory structure and the second memory structure are centrally symmetrical. The present disclosure can eliminate a problem of asymmetrical weight reading sensing of the memory array when the gate width/gate length (W/L) of the transistor is small.

### TECHNICAL FIELD

The present disclosure relates to a technical field of a memory, and more specifically, to a memory array and an in-memory computing circuit.

### BACKGROUND

The artificial intelligence market has experienced significant growth in recent years, especially in areas such as speech recognition and machine vision. At the same time, with the increasing popularity of smart terminals such as smartphones, smart watches and smart bracelets, the market demand for high energy-efficient hardware is also increasing. However, the traditional computing architecture relies on a von Neumann architecture, in which a processor and a memory are separated, the processor retrieves data from the memory, processes the data, and then stores the data back into the memory. This process requires a large amount of data transferring between the processor and the memory, resulting in significant increases in energy consumption and time delay.

At present, in order to alleviate the above problems, the conventional solution is to use new devices such as a resistive memory, a phase change memory, a magnetic memory and a ferroelectric memory to realize data in-memory computing. These new resistive memory devices use the resistance value of the device to store data, allowing multiple bits to be stored in a single cell. In an array, the new resistive memory may use Ohm's law and Kirchhoff's law to perform Multiply-Accumulate operation in an analog domain, thereby accelerating artificial intelligence calculations. Therefore, in-memory computing chips based on new resistive memories have been widely studied in recent years.

Among them, one of the keys to perform Multiply-Accumulate operation for the new resistive memory is a weight mapping scheme, which maps algorithm parameters (such as weights in neural networks) into resistance values and stores them in the resistive memory array. However, due to the asymmetric electrical connection relationship between transistors and the storage in traditional resistive memory arrays, there is a problem of asymmetrical weight reading sensing in reading the in-memory computing applications. The problem of asymmetrical weight reading sensing makes the gate voltage of transistors in the 1T1R structure that stores the positive and negative parts of the weight unstable, which degrades the recognition accuracy of in-memory computing arrays with transistors with a small gate width/gate length (W/L).

It can be seen that in traditional array structures, as well as in-memory computing systems in which the basic memory cell comprises transistors and resistive devices, such as the resistive memory, the phase change memory, the magnetic memory and the ferroelectric memory, integrated in series, they will face the problem of asymmetrical weight reading sensing, resulting in reduced accuracy. Enlarging the size of the transistors or overdriving the transistors cannot completely save the loss of accuracy, and may also lead to higher power consumption and reduced reliability.

### SUMMARY

In view of the above problems, the present disclosure provides a memory array and an in-memory computing circuit to solve the problems existing in existing memory devices, such as asymmetrical weight reading sensing, resulting in reduced accuracy and cannot meet the recognition accuracy of the in-memory computing array with transistors with small gate width/gate length.

A memory array according to the present disclosure comprises memory cells arranged in an array, wherein each of the memory cells comprises a first memory structure and a second memory structure that are complementary to each other, wherein, the first memory structure comprises a first transistor and a first memory connected to a drain electrode of the first transistor, wherein, the second memory structure comprises a second transistor and a second memory connected to a drain electrode of the second transistor, and wherein the first memory structure and the second memory structure are isolated from each other, and the first memory structure and the second memory structure are centrally symmetrical.

In addition, an optional technical solution is that a current direction is set to flow from the second memory structure to the first memory structure, wherein, a gate electrode of the first transistor is connected to a word line WL⁻, a source electrode of the first transistor is connected to a bit line BL⁻, and the first memory is connected to a source electrode line SL, and wherein a gate electrode of the second transistor is connected to a word line WL⁺, a source electrode of the second transistor is connected to the source electrode line SL, and the second memory is connected to a bit line BL⁺.

In addition, an optional technical solution is that when an external input signal is applied to the word line WL⁻ and the word line WL⁺, if the input signal represents “1”, a voltage applied to a gate electrode of the second memory structure is: V_{ref}+V_{G}, and a voltage applied to a gate electrode of the first memory structure is: V_{ref}+V_{G}−V_{read}, and if the input signal represents “0”, the voltage applied to the gate electrode of the second memory structure is: V_{ref}, and the voltage applied to the gate electrode of the first memory structure is: V_{ref}−V_{read}, wherein, V_{read} represents the read voltage, V_{ref} represents the reference voltage, V_{G} represents a predetermined gate voltage, and V_{ref} and V_{G} are fixed values.

In addition, an optional technical solution is that a read voltage is applied to the bit line BL; and the bit line BL⁺, a voltage on the bit line BL⁻ is: V_{BL}⁻=V_{ref}−V_{read}, and a voltage on the bit line BL⁺ is: V_{BL}⁺=V_{ref}+V_{read}, and wherein V_{read} represents the read voltage, and V_{ref} represents the reference voltage.

In addition, an optional technical solution is that when an external input signal is applied to the bit line BL⁻ and the bit line BL⁺, a voltage applied to a gate electrode of the second memory structure is: V_{ref}+V_{G}, and a voltage applied to agate electrode of the first memory structure is: V_{ref}+V_{G}−V_{read}, and wherein, V_{read} represents a read voltage, V_{ref} represents a reference voltage, V_{G} represents a predetermined gate voltage, and V_{ref} and V_{G} are fixed values.

In addition, an optional technical solution is that if the input signal represents “0”, voltages on the bit line BL; and the bit line BL⁺ are: V_{BL}⁺=V_{BL}=V_{ref}, and if the input signal represents x, the voltage on the bit line BL⁺ is: V_{BL}⁺=V_{ref}+Vᵢₙ, and the voltage on the bit line BL⁻ is: V_{BL}⁻=V_{ref}−Vᵢₙ, wherein, Vᵢₙ=x·V_{read}.

In addition, an optional technical solution is that the first transistor and the second transistor are metal oxide semiconductor field effect transistors and wherein the first memory and the second memory are resistive memories, phase change memories, ferroelectric memories and magnetic memories.

In addition, an optional technical solution is that channel types of the first transistor and the second transistor are the same.

On the other hand, the present disclosure also provides an in-memory computing circuit, comprising the above-mentioned memory array.

By utilizing the above-mentioned memory array and in-memory computing circuit, the first memory structure and the second memory structure complementary to each other are provided, and the first memory structure and the second memory structure are set to be isolated, so that they have electrically symmetrical properties. When the memory array performs cumulative calculations, the problem of asymmetrical weight reading sensing can be eliminated. At the same time, the accuracy of the calculation can be improved, and a small gate width/gate length of the transistor can be maintained, thereby improving the integration density of the array and the overall performance of the memory.

In order to achieve the above and related purposes, one or more aspects of the present disclosure comprises the features that will be described in detail later. The following description and the accompanying drawings describe some exemplary aspects of the present disclosure in detail. However, these aspects indicate only some of the various ways in which the principles of the present disclosure can be used. In addition, the present disclosure is intended to comprise all these aspects and their equivalents.

### BRIEF DESCRIPTION OF DRAWINGS

By referring to the following description in conjunction with the drawings, and with a more comprehensive understanding of the present disclosure, other objects and results of the present disclosure will become clearer and easier to understand. In the drawings:

FIG. 1 is a schematic diagram of a structure of a memory array according to a first embodiment of the present disclosure;

FIG. 2 is a schematic diagram of a voltage according to the first embodiment of the present disclosure;

FIG. 3 is a schematic diagram of a structure of a memory array according to a second embodiment of the present disclosure; and

FIG. 4 is a schematic diagram of a voltage according to the second embodiment of the present disclosure.

The same reference numerals throughout the drawings indicate similar or corresponding features or functions.

### DETAILED DESCRIPTIONS

In the following description, for the purpose of illustration, in order to provide a comprehensive understanding of one or more embodiments, many specific details are set forth. However, it is apparent that these embodiments may also be implemented without these specific details. In other examples, for ease of describing one or more embodiments, known structures and devices are shown in the form of block diagrams.

In the description of the present disclosure, it is to be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicating orientations or positional relationships based on the orientations or positional relationships shown in the drawings, are only for the convenience of describing the present disclosure and simplifying the description, and do not indicate or imply that the device or the element referred to must have a specific orientation, be constructed and operated in a specific orientation, and therefore should not be understood as limiting the present disclosure.

In order to solve the problems existing in the existing memory solutions, such as asymmetrical weight reading sensing, which leads to reduced accuracy and cannot meet the recognition accuracy of the in-memory computing array with transistors with small gate width/gate length, the present disclosure provides a memory array and an in-memory computing circuit, in which the first and second memory structures complementary to each other are provided, and the first and second memory structures are set to be isolated to form a centrally symmetrical 2T2R structure, so that it has a symmetrical property of electrical connection relationship, and when the memory array performs Multiply-Accumulate calculation, the asymmetrical weight reading sensing problem can be eliminated, and at the same time, the accuracy of the calculation can be improved, and it is applicable to transistors with small gate width/gate length, thereby improving the integration density of the array and the overall performance of the memory.

To describe the memory array and the in-memory computing circuit of the present disclosure in detail, specific embodiments of the present disclosure will be described in detail below with reference to the drawings.

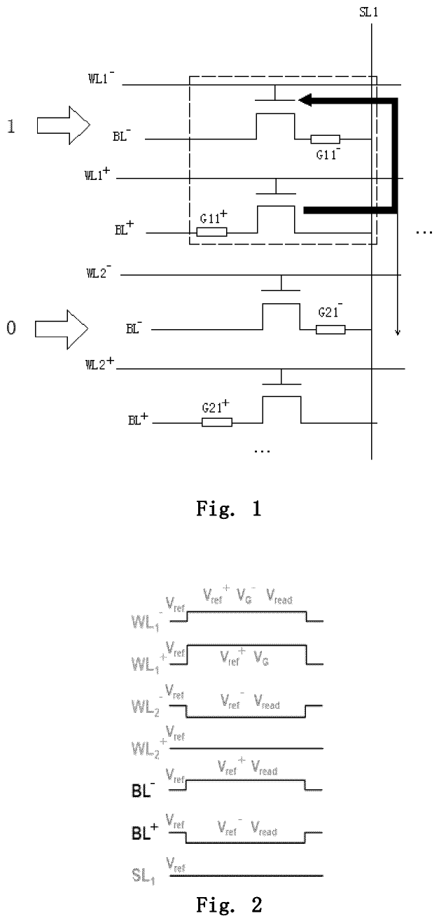

FIG. 1 illustrates a schematic structure of a memory array according to a first embodiment of the present disclosure, and FIG. 2 illustrates a schematic principle of a voltage of the memory array according to the first embodiment.

As shown in FIGS. 1 and 2, the memory array of an embodiment of the present disclosure comprises a plurality of memory cells arranged in an array, wherein each memory cell further comprises a first memory structure and a second memory structure complementary to each other, wherein the first memory structure comprises a first transistor and a first memory connected to a drain electrode of the first transistor; the second memory structure comprises a second transistor and a second memory connected to a drain electrode of the second transistor, and the first memory structure and the second memory structure are isolated from each other, so that the first memory structure and the second memory structure are centrally symmetrical, weight symmetrical, or topologically symmetrical, thereby overcoming the weight reading problem existing in the asymmetric 2T2R structure.

Specifically, in the memory array of the embodiment of the present disclosure, a current direction is set to be indicated by an arrow, flowing from the second memory structure to the first memory structure. At this time, a gate electrode of the first transistor is connected to the word line WL⁻, a source electrode of the first transistor is connected to the bit line BL, and the first memory is arranged on the drain electrode side and connected to a source line SL, and a gate electrode of the second transistor is connected to a word line WL⁺, a source electrode of the second transistor is connected to the source electrode line SL, and the second memory is arranged on the drain electrode side and connected to the bit line BL⁺.

It can be seen that when the resistive memory performs Multiply-Accumulate operation, the key process is the weight mapping scheme, which maps the algorithm parameters into resistance values and stores them in the memory array. For example, in a typical feedforward neural network, the connection strength between each neuron is determined by the weight between them. The weight has both positive and negative values. Therefore, the actual weight-to-resistance mapping process is usually achieved by subtraction of the resistance values of two memory structures (W⁺ and W⁻), that is, the storage of the weight is achieved by a 2T2R array.

Specifically, the traditional 2T2R array mainly stores W⁺ and W⁻ on different bit lines (BL), and the input signal is input from the bit line, which can be a binary value or multiple values. The difference between the memory storage states on two adjacent bit lines represents the weight in the neural network. However, since the read voltages applied to adjacent bit lines of the traditional 2T2R array are inconsistent in positive and negative, storing the 1T1R structure W⁺ and W⁻ has an asymmetric topological connection relationship, which makes the traditional 2T2R array have a problem of asymmetrical weight reading sensing. The problem of asymmetrical weight reading sensing makes the gate voltage of the transistor in the 1T1R structure storing W⁺ and W⁻ unstable, which degrades the recognition accuracy of the in-memory computing arrays with transistors with a small gate width/gate length (W/L). However, the present disclosure can make the 2T2R structure have a completely electrically symmetrical property by isolating and improving the 1T1R structure in the memory cell, thereby enhancing the accuracy and integration of the memory array in the in-memory computing application.

In a specific embodiment of the present disclosure, an external input signal is applied to the word line WL; and the word line WL⁺. If the input signal represents “1”, the input signal on the word line WL⁺ is +1, and the input signal on the word line WL⁻ is −1. At this time, the voltage applied to the gate electrode of the second memory structure (W⁺) is: V_{ref}+V_{G}, and the voltage applied to the gate electrode of the first memory structure (W⁻) is: V_{ref}+V_{G}−V_{read}; if the input signal represents “0”, the input signals on the word line WL⁺ and the word line WL⁻ are both 0, the voltage applied to the gate electrode of the second memory structure is: V_{ref}, and the voltage applied to the gate electrode of the first memory structure is: V_{ref}−V_{read}; wherein, V_{read} represents the read voltage, V_{ref} represents the reference voltage, V_{G} represents the predetermined gate voltage, and V_{ref} and V_{G} are fixed values. Since V_{gs}=V_{G}+V_{ref}, and the values of V_{G} and V_{ref} are constant, the V_{gs} value is also constant and will not change with changes in current and resistance.

Among them, the read voltage V_{read} is applied to the bit line BL; and the bit line BL⁺, the voltage on the bit line BL⁻ is: V_{BL}⁻=V_{ref}−V_{read}, and the voltage on the bit line BL⁺ is: V_{BL}⁺=V_{ref}+V_{read}, wherein, V_{read} represents the read voltage, and V_{ref} represents the reference voltage, therefore, the asymmetrical weight reading sensing can be canceled through the memory cell structure and bias.

It should be noted that, in order to achieve symmetry as much as possible, the transistors of the first memory structure and the second memory structure in the above-mentioned memory cell need to be isolated, which can be achieved by additional N-wells and deep N-wells, or by deep trenches, isolation media or other processes. In addition, different substrate voltages (Vsub) are applied to the transistor parts of the first memory structure and the second memory structure, respectively, so that the width of the transistor can be designed according to the minimum W/L allowed by the technology node, thereby improving the integration advantage while ensuring the calculation accuracy.

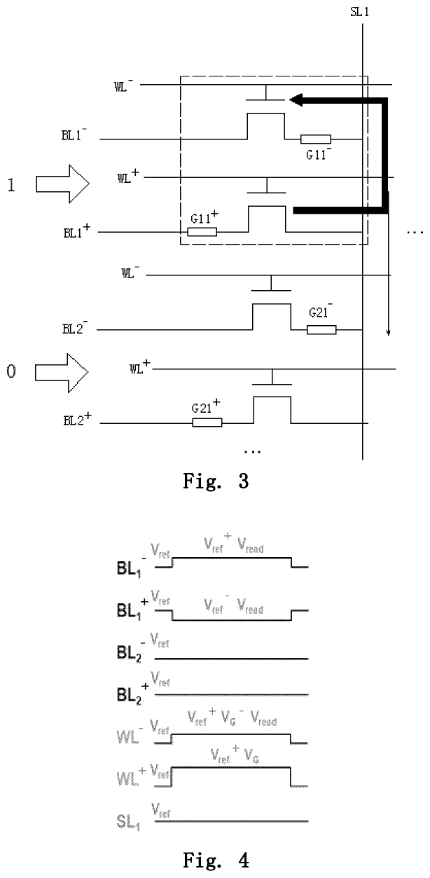

FIG. 3 illustrates a distribution structure of a memory array according to another embodiment of the present disclosure, and FIG. 4 illustrates a schematic principle of a voltage of a memory array according to another embodiment of the present disclosure.

As shown in FIG. 3 and FIG. 4, the memory array of this embodiment of the present disclosure comprises a plurality of memory cells arranged in an array, wherein each memory cell further comprises first memory structure and second memory structure complementary to each other; wherein the first memory structure comprises a first transistor and a first memory connected to the drain electrode of the first transistor; the second memory structure comprises a second transistor and a second memory connected to the drain electrode of the second transistor, and the first memory structure and the second memory structure are isolated by an N-well, a deep trench, a medium or other processes, so that the first memory structure and the second memory structure are arranged in a central symmetric, a weight symmetric or a topological symmetric manner, thereby overcoming the problem of asymmetrical weight reading sensing existing in the conventional 2T2R structure.

Specifically, in this embodiment, the external input signal is applied to the bit line BL⁻ and the bit line BL⁺, the voltage applied to the gate electrode of the second memory structure is: V_{ref}+V_{G}, and the voltage applied to the gate electrode of the first memory structure is: V_{ref}+V_{G}−V_{read}, wherein, V_{read} represents the read voltage, V_{ref} represents the reference voltage, and V_{G} represents the predetermined gate voltage; V_{ref} and V_{G} are fixed values.

Among them, if the input signal represents “0”, the voltages on the bit line BL; and the bit line BL⁺ are the same, and are expressed as: V_{BL}⁺=V_{BL}⁻=V_{ref}; if the input signal represents x, the signals input to the bit line BL and the bit line BL⁺ represent x and −x, respectively. At this time, the voltage on the bit line BL⁺ is: V_{BL}+=V_{ref}+Vᵢₙ, and the voltage on the bit line BL⁻ is: V_{BL}⁻=V_{ref}−Vᵢₙ, wherein, Vᵢₙ=x·V_{read}. It can be seen that although this embodiment changes the input position of the input signal, it can still eliminate asymmetrical weight reading sensing.

It should be noted that applying the input signal to the above-mentioned two bit lines can support binary input and analog input. During the input process, the mapping of parameter weights to device conductance is reasonably designed, to match the linear region of the transistor, so that the input voltage and output current of the transistor roughly follow Ohm's law.

In the above two specific embodiments of the present disclosure, the default transistors are N-channel transistors. If P-channel transistors are used, the current direction will change, but the above-mentioned asymmetrical weight reading sensing problem can still be solved. Therefore, the channel type of the specific transistor is not limited, and it is sufficient to ensure that the channel types of the first transistor and the second transistor are the same.

In addition, the first transistor and the second transistor are preferably metal oxide semiconductor field effect transistors compatible with the CMOS process, and of course other transistors that can meet the requirements of the in-memory computing architecture can also be used; similarly, the first memory and the second memory are preferably memories made of resistive materials compatible with the CMOS process, and other devices that store information through resistance can also be used, such as resistive memory, phase change memory, ferroelectric memory, magnetic memory, and any other memory device that uses resistance to distinguish different storage states.

In the specific application process, in the traditional 2T2R array structure, the output currents of the W⁺ and W⁻ cells of transistors with different W/L vary greatly. Ideally, the output currents of W⁺ and W⁻ in two rows with the same W/L should be the same, since they represent the same absolute weight. However, it can be seen through simulations and experimental structures that as W/L becomes larger (W/L>13), a significant deviation occurs between the output currents of its two cells.

However, in the memory array structure of the present disclosure, i.e., the centrally symmetric 2T2R structure, it can be concluded from simulation results and measured experimental data that the deviation of the output currents of the two cells is eliminated, thereby successfully solving the problem of asymmetrical weight reading sensing.

Specifically, according to the network simulation results, in the traditional 2T2R structure, when W/L=3, all networks show a serious reduction in recognition accuracy; this problem still exists when W/L=13; when W/L=27, although the recognition accuracy is restored, there is still a 1-2% reduction in recognition accuracy compared with the ideal situation. However, in the centrosymmetric 2T2R structure of the present disclosure, all networks have high recognition accuracy, and even at extremely small W/L, the network can still achieve high recognition accuracy, and can achieve dense integration of in-memory computing arrays by reducing W/L. Under the condition of maintaining similar recognition accuracy, the integration density of the memory can be increased by 42.2% compared with the traditional 2T2R structure.

On the other hand, the present disclosure further provides an in-memory computing circuit, comprising the above-mentioned memory array. It should be noted that the embodiments of the in-memory computing circuit of the memory array can refer to the description of the memory array embodiment, which will not be repeated here.

According to the above-mentioned scheme of the memory array and the in-memory computing circuit of the present disclosure, a centrally symmetrical 2T2R structure is adopted, and the 2T2R is composed of two complementary 1T1R structures. Each resistive memory structure is integrated at the drain end of the topological structure of the corresponding transistor, ensuring that the source electrode of the transistor in the centrally symmetrical 2T2R is always connected to a fixed voltage potential. At the same time, in order to achieve complete symmetry, the transistors in the centrally symmetrical 2T2R need to be isolated by an accessory N well and a deep N well, a medium or a deep trench, etc., so as to eliminate the problem of asymmetrical weight reading sensing faced by the traditional structure when performing multiplication, addition and accumulation calculations, improve the network accuracy while maintaining a very small W/L, and improve the array integration density of the in-memory computing chip.

The memory array and the in-memory computing circuit according to the present disclosure are described as examples with reference to the accompanying drawings. However, it should be understood by those skilled in the art that various improvements can be made to the memory array and the in-memory computing circuit proposed by the present disclosure without departing from the content of the present disclosure. Therefore, the protection scope of the present disclosure should be determined by the content of the attached claims.

What is claimed is:

1. A memory array, comprising memory cells arranged in an array, wherein each of the memory cells comprises a first memory structure and a second memory structure that are complementary to each other,
wherein, the first memory structure comprises a first transistor and a first memory connected to a drain electrode of the first transistor,
wherein, the second memory structure comprises a second transistor and a second memory connected to a drain electrode of the second transistor, and
wherein, the first memory structure and the second memory structure are isolated from each other, and topological structures of the first memory structure and the second memory structure are centrally symmetrical,
wherein a current direction is set to flow from the second memory structure to the first memory structure,
wherein, a gate electrode of the first transistor is connected to a word line WL⁻, a source electrode of the first transistor is connected to a bit line BL⁻, and the first memory is connected to a source line SL, and
wherein, a gate electrode of the second transistor is connected to a word line WL⁺, a source electrode of the second transistor is connected to the source line SL, and the second memory is connected to a bit line BL⁺.

2. The memory array according to claim 1, wherein when an external input signal is applied to the word line WL⁻ and the word line WL⁺,
if the input signal represents “1”, a voltage applied to a gate electrode of the second memory structure is: V_{ref}+V_{G}, and a voltage applied to a gate electrode of the first memory structure is: V_{ref}+V_{G}−V_{read}, and
if the input signal represents “0”, the voltage applied to the gate electrode of the second memory structure is: V_{ref}, and the voltage applied to the gate electrode of the first memory structure is: V_{ref}−V_{read},
wherein, V_{read} represents a read voltage, V_{ref} represents a reference voltage, V_{G} represents a predetermined gate voltage, and V_{ref} and V_{G} are fixed values.

3. The memory array according to claim 2,
wherein, the read voltage is applied to the bit line BL⁻ and the bit line BL⁺, a voltage on the bit line BL is: V_{BL}⁻=V_{ref}−V_{read}, and a voltage on the bit line BL⁺ is: V_{BL}+=V_{ref}+V_{read}, and
wherein, V_{read} represents the read voltage, and V_{ref} represents the reference voltage.

4. The memory array according to claim 1, wherein when an external input signal is applied to the bit line BL⁻ and the bit line BL⁺,
a voltage applied to a gate electrode of the second memory structure is: V_{ref}+V_{G}, and a voltage applied to a gate electrode of the first memory structure is: V_{ref}+V_{G}−V_{read}, and
wherein, V_{read} represents a read voltage, V_{ref} represents a reference voltage, V_{G} represents a predetermined gate voltage, and V_{ref} and V_{G} are fixed values.

5. The memory array according to claim 4,
wherein, if the input signal represents “0”, voltages on the bit line BL; and the bit line BL⁺ are: V_{BL}⁺=V_{BL}⁻=V_{ref}, and
if the input signal represents x, the voltage on the bit line BL⁺ is: V_{BL}+=V_{ref}+Vᵢₙ, and the voltage on the bit line BL⁻ is: V_{BL}⁻=V_{ref}−Vᵢₙ,
wherein, Vᵢₙ=x·V_{read}.

6. The memory array according to claim 1,
wherein the first transistor and the second transistor are metal oxide semiconductor field effect transistors, and
wherein the first memory and the second memory are resistive memories, phase change memories, ferroelectric memories and magnetic memories.

7. The memory array according to claim 1,
wherein channel types of the first transistor and the second transistor are the same.

8. An in-memory computing circuit, comprising the memory array of claim 1.
